(19) United States
(12) Patent Application Publication
(10) Pub. No.: US 2026/0165176 A1
(43) Pub. Date: Jun. 11, 2026

(54) BONDING APPARATUS AND A BONDING METHOD

(71) Applicant: STATS ChipPAC Pte. Ltd., Singapore (SG)

(72) Inventors: DongSam PARK, Incheon (KR); TaeKeun LEE, Incheon (KR); Hyungsuk MIN, Incheon (KR)

(21) Appl. No.: 19/178,893

(22) Filed: Apr. 15, 2025

(30) Foreign Application Priority Data
Apr. 15, 2024 (CN) 202410450070.0

(51) Int. Cl. H10W 72/00; H10P 72/00

(52) U.S. Cl. CPC H10W 72/07141; H10P 72/0446; H10W 72/07232

(57) ABSTRACT

A bonding apparatus and a bonding method are provided. The bonding apparatus comprises: a bonding platform having a base portion; a head portion extending upward from the base portion; and base slots formed in the base portion; a jig configured for clamping a substrate, wherein the jig comprises jig holes extending vertically within the jig and being aligned with the base slots; a top cover configured for covering at least a portion of a top surface of the substrate; and push rods each being at least partially accommodated within one of the base slots and vertically movable relative to the bonding platform between a retracted position and an elevated position; wherein in the retracted position, the top cover is in direct contact with the substrate; and in the elevated position, the top cover is pushed upward off the substrate and the jig by the push rods.

### TECHNICAL FIELD

The present application generally relates to semiconductor technology, and more particularly, to a bonding apparatus and a bonding method.

### BACKGROUND OF THE INVENTION

In semiconductor industry, laser assisted bonding (LAB) technology is widely used in chip assembling processes. During an LAB procedure when a semiconductor die is bonded onto a substrate via solder bumps and flux materials, a top cover is applied on the substrate to prevent substrate warpage. Additionally, in a subsequent flux cleaning process, the top cover may be helpful to prevent cracks of the solder bumps at corners of the semiconductor die, which may be induced by water pressure during the cleaning process.

In recent years, there is a growing application of laser compression bonding (LCB) technology due to its high bonding accuracy and efficiency. For an LCB process, a semiconductor die is bonded onto a substrate via solder bumps and flux materials with an in-situ bonding mechanism without self-alignment of the solder bumps with conductive pads on the substrate, and the expansion and shrinkage of the substrate may be essential factors affecting the alignment of the solder bumps with the conductive pads on the substrate. On basis of this, a top cover applied on the substrate may induce irregular substrate expansion, resulting in poor alignment of the solder bumps with the conductive pads on the substrate. As such, it is desired to remove the top cover during the LCB process, but the top cover should be applied in a subsequent flux cleaning process to prevent the solder bumps from cracking.

Therefore, a need exists for a bonding apparatus which can operably attach a top cover onto a substrate and remove the top cover from the substrate during a bonding process, to improve joint quality of the bonding process.

### SUMMARY OF THE INVENTION

An objective of the present application is to provide a bonding apparatus to improve joint quality of the bonding process.

According to an aspect of the present application, a bonding apparatus is provided. The bonding apparatus comprises: a bonding platform configured for operably holding a substrate, wherein the bonding platform comprises: a base portion; a head portion extending upward from the base portion and configured for supporting the substrate when the bonding platform is holding the substrate; and base slots formed in the base portion and around the head portion; a jig disposed around the head portion of the bonding platform and configured for clamping the substrate, wherein the jig comprises jig holes each extending vertically within the jig and being aligned with one of the base slots; a top cover operably attached to the jig and configured for covering at least a portion of a top surface of the substrate when the top cover is attached to the jig; and push rods each being at least partially accommodated within one of the base slots and vertically movable relative to the bonding platform between a retracted position and an elevated position; wherein in the retracted position, the push rods are not higher than the jig such that the substrate is supported by the head portion and the top cover is in direct contact with the substrate; and in the elevated position, the push rods move through the respective jig holes and extend from the jig such that the top cover is pushed upward off the substrate and the jig.

According to another aspect of the present application, a bonding method is provided, wherein the bonding method is implemented by a bonding apparatus comprising: a compression head, a bonding platform comprising a base portion, a head portion extending upward from the base portion, and base slots formed in the base portion and around the head portion; a jig disposed around the head portion of the bonding platform, wherein the jig comprises jig holes each extending vertically within the jig and being aligned with one of the base slots; a top cover attached to the jig and covering at least a portion of a top surface of the substrate; and push rods each being at least partially accommodated within one of the base slots. The bonding method comprises: clamping a substrate between the top cover and the jig; moving the bonding platform towards the top cover and the jig to load the substrate on the head portion of the bonding platform; moving the push rods through the respective jig holes to an elevated position to push the top cover upward off the jig and the substrate; placing a semiconductor die onto the substrate and pressing the semiconductor die against the substrate by the compression head to bond the semiconductor die with the substrate via solder bumps; and retracting the push rods down through the respective jig holes to cover the substrate by the top cover and clamp the substrate between the jig and the top cover.

According to another aspect of the present application, a bonding apparatus is provided. The bonding apparatus comprises: a bonding platform configured for operably holding a substrate, wherein the bonding platform comprises: a base portion; and a head portion extending upward from the base portion and configured for supporting the substrate when the bonding platform is holding the substrate; a jig disposed around the head portion of the bonding platform and configured for clamping the substrate; a top cover operably attached to the jig and configured for covering at least a portion of a top surface of the substrate when the top cover is attached to the jig; and actuators each being coupled to the top cover and vertically movable relative to the bonding platform between a retracted position and an elevated position; wherein in the retracted position, the actuators are lowered down such that the substrate is supported by the head portion and the top cover is in direct contact with the substrate; and in the elevated position, the actuators are lifted relative to the bonding platform such that the top cover is pushed upward off the substrate and the jig.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate various steps of a bonding method implemented by a bonding apparatus according to a first embodiment of the present application.

FIGS. 2A to 2C illustrate various steps of a bonding method implemented by a bonding apparatus according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, for a laser compression bonding process, a semiconductor die is bonded onto a substrate via solder bumps and flux materials through an in-situ bonding mechanism without self-alignment of the solder bumps with conductive pads on the substrate. Based on this, the expansion and shrinkage of the substrate may be essential factors affecting the alignment of the solder bumps with the conductive pads on the substrate. A top cover applied on the substrate may limit the substrate expansion in some directions, which may result in irregular substrate expansion and poor alignment of the solder bumps with the conductive pads. As such, it is desired to remove the top cover during the laser compression bonding process, which, however, needs to be applied in a subsequent flux cleaning process to prevent solder bumps from cracking.

To address this issue, a new bonding apparatus is provided to implement a new bonding process. To be more specific, the bonding apparatus includes actuators which can move vertically to operably push a top cover which is previously placed on a substrate upward off the substrate or lower the top cover down onto the substrate during a different step of the bonding process. The bonding apparatus can be used in a laser compression bonding process to improve the joint quality between the semiconductor die and the substrate.

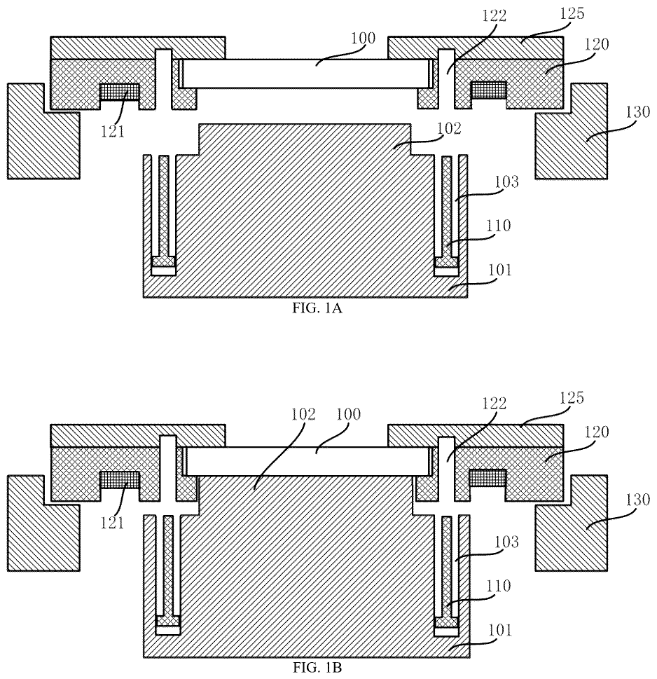

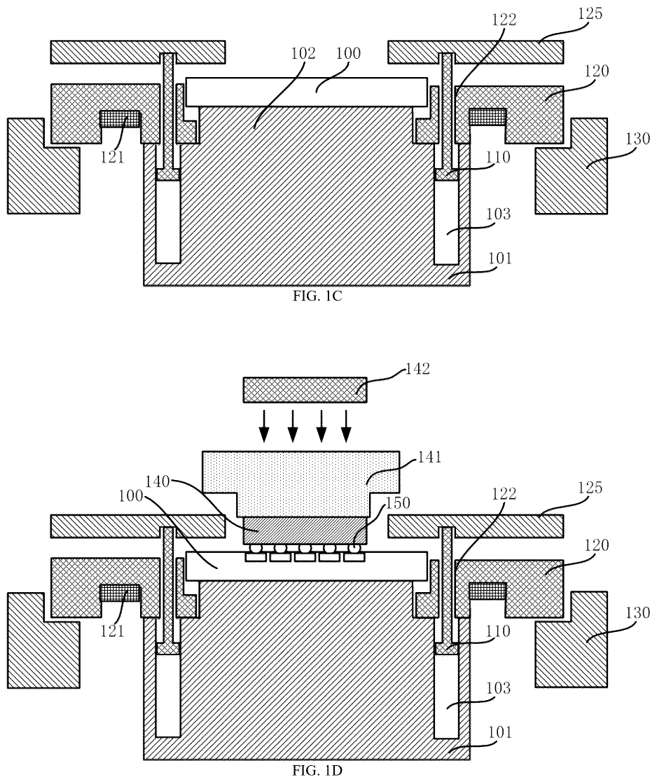

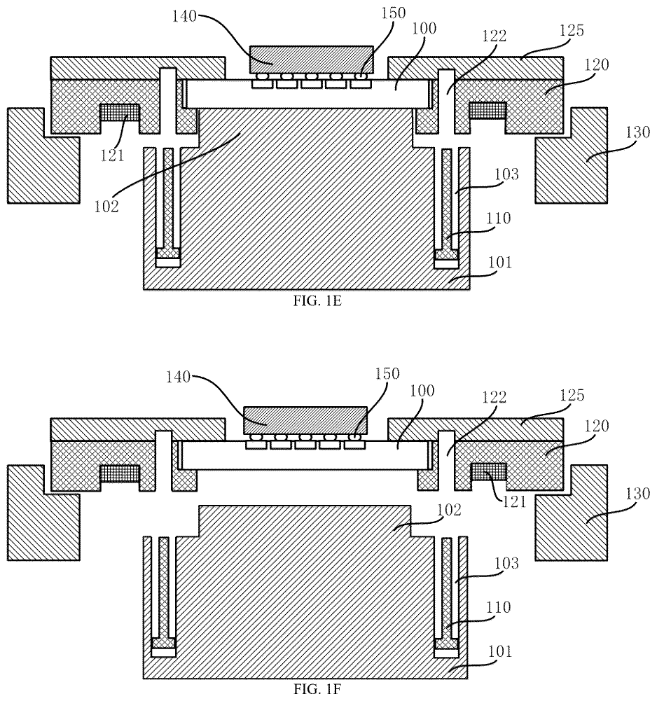

FIGS. 1A to 1F illustrate various steps of a bonding method implemented by a bonding apparatus according to a first embodiment of the present application.

As shown in FIG. 1A, a bonding apparatus is provided, which may be used for bonding a semiconductor die 140 onto a substrate 100. The bonding apparatus includes a bonding platform which may hold the substrate 100 when the semiconductor die 140 is being bonded onto the substrate 100 or prior to such bonding process for preparation. To be more specific, the bonding platform includes a base portion 101, and a head portion 102 extending upward from the base portion 101. In some embodiments, the substrate 100 may be loaded onto the head portion 102, in which case a top surface of the head portion 102 may be in direct contact with a bottom surface of the substrate 100. The head portion 102 has a size smaller than that of the base portion 101, and may, for example, be arranged in a central region of the base portion 101 with a top surface of the base portion 101 surrounding the head portion 102 at a lower level. In other words, the bonding platform defines a step structure at its periphery which extends from the top surface of the head portion 102 to the top surface of the base portion 101. In some embodiments, the head portion 102 may have a rectangular layout, which may be similar to a shape of a semiconductor die. In some other embodiments, the head portion 102 may have other shaped layouts, such as a circle, a hexagon or an octagon.

The base portion 101 further includes base slots 103 formed in the base portion 101 and around the head portion 102. The base slots 103 may extend vertically from an interior to the top surface of the base portion 101. Multiple push rods 110 may be accommodated within the base slots 103, each of which is arranged in one of the base slots 103. The push rods 110 are vertically movable relative to the bonding platform through the base slots 103. In the embodiment shown in FIG. 1A, each of the push rods 110 may include an elongated shaft with an enlarged head at the bottom of the elongated shaft. The enlarged head may help the push rod 110 to keep balance and avoid tilting when the push rod 110 moves within the respective base slot 103. In some embodiments, the enlarged head may not be in direct contact with an inner wall of the base slot 103, which facilitates smooth movement of the push rods 110 within the respective base slots 103. In some other embodiments, the enlarged head may be in direct contact with the inner wall of the base slot 103. In some other embodiments, the push rods 110 may have a cross section of cylinder, cuboid, etc. It can be appreciated that the push rods 110 can be mating with the base slots 103 in the size and shape, allowing for accommodation and movement of the push rods 110 within the respective base slots 103.

Still referring to FIG. 1A, the bonding apparatus further includes a jig 120 disposed around the head portion 102 of the bonding platform, which is mating with the step structure of the bonding platform. The substrate 100 may have a size larger than that of the head portion 102 of the bonding platform, and the substrate 100 may be clamped by the jig 120 at a periphery of the substrate 100. In some embodiments, the jig 120 may include a clamping base and an extended portion extending from the clamping base. The clamping base may be in contact with a lateral surface of the substrate 100 with the extended portion attached on the bottom surface of the substrate 100 to tightly hold the substrate 100. A top surface of the jig 120 may be aligned with a top surface of the substrate 100 to form a flat surface. In some embodiments, the substrate 100 may be first placed on a work stage to facilitate the clamping of the jig 120 with the substrate 100. In some embodiments, the bonding apparatus includes more than one jig 120, which may be distributed around the substrate 100 in a symmetrical layout, for example.

The bonding apparatus may further include a rail 130 that is mechanically coupled to the jig 120, or multiple rails 130 coupled to multiple jigs 120, respectively. Each rail 130 is capable of moving the corresponding jig 120 vertically with respect to the bonding platform during a different step of the bonding process. In some embodiments, a drive mechanism may be mounted on each of the rails 130 to control vertical movements of the jig 120. In some other embodiments, the substrate may have a different thickness, and the jig may be moved upward or downward by the rail to adjust the top surface of the jig, thereby aligning it with the top surface of the substrate to form a flat surface.

Still referring to FIG. 1A, the jig 120 further includes jig holes 122 each extending vertically within the jig 120. Each of the jig holes 122 is aligned with one of the base slots 103 below it, which allows for the push rods 110 to enter into the respective jig holes 122 through the base slots 103 or vice versa. It can be appreciated that the jig holes 122 may have a cross section that is substantially the same as that of the base slot 103, or a slightly bigger or smaller cross section.

Furthermore, a top cover 125 is attached to the jig 120 and covers a portion of the top surface of the substrate 100, for example, at its periphery. Therefore, the substrate 100 may then be clamped between the top cover 125 and the jig 120 to avoid displacement. In some embodiments, the jig 120 further includes at least a magnet 121 embedded within the jig 120, and the top cover 125 includes stainless steel or other similar ferromagnetic materials that can be attracted by magnet. As such, the top cover 125 can be attracted by the magnet(s) 121 within the jig 120 and is thus fixed to the top surface of the substrate 100 and the jig 120. The magnet(s) 121 may include at least one material from iron, nickel and cobalt and their alloys, some alloys of rare-earth metals, and some naturally occurring minerals such as lodestone. In some embodiments, the top cover 125 may also include alignment slots extending vertically from a bottom surface to an interior of the top cover 125 with each of the alignment slots being aligned with one of the jig holes 122. A height of the alignment slot may not be larger than that of the top cover 125, i.e., the alignment slot may not extend through the top cover 125, and thus elevation of the top cover 125 via the push rods 110 in a subsequent step can be easier. In some other embodiments, the top cover 125 may not include alignment slots.

As shown in FIG. 1A, the bonding process is not substantially implemented, rather, the bonding apparatus is in a prep step to prepare for the subsequent processes. In particular, the bonding platform is placed below and away from the substrate 100, which provides sufficient room to clamp the substrate 100 between the top cover 125 and the jig 120.

Next, the bonding platform is moved towards the top cover 125 and the jig 120 to load the substrate 100 on the head portion 102 of the bonding platform. As shown in FIG. 1B, the bottom surface of the substrate 100 is now in direct contact with the top surface of the head portion 102, and the jig 120 is accommodated within the step structure of the bonding platform. To be more specific, each of the jig holes 122 is vertically aligned with a respective base slot, which provides a passage for a respective push rod 110 to move upwards to push the top cover 125 in a subsequent step.

In the embodiment shown in FIG. 1B, the jig 120 has a smaller height compared with a total height of the substrate 100 and the head portion 102 of the bonding platform, and there exists a gap between the bottom surface of the jig 120 and the top surface of the base portion 101.

Furthermore, the bonding platform has air vents which may be distributed across the whole bonding platform. The air vents are fluidly coupled to a vacuum source to apply a vacuum pressure to hold the substrate 100. In some embodiments, the air vents may include a plurality of pores distributed across the whole bonding platform to provide a uniform vacuum pressure across the substrate 100. In some other embodiments, the air vents may include interconnected channels or pipelines therebetween. In some alternative embodiments, the air vents may be only distributed across the head portion 102 where the substrate 100 is placed.

Next, as shown in FIG. 1C, the push rods 110 may move through the respective jig holes 122 and extend from the jig holes 122 to push the top cover 125 upward off the jig 120 and the substrate 100, which is referred to as an elevated position. To be more specific, the push rods 110 may first move upward within the base slots 103, then enter into the respective jig holes 122, and finally be in contact with the bottom surface of the top cover 125. Then the push rods 110 may continue to move upward and extend from the jig holes 122, therefore pushing the top cover 125 off the jig 120 and the substrate 100 to expose the top surface of the substrate 100. In some embodiments, the base slots 103 and the push rods 110 may be arranged in a symmetric layout around the substrate 100, which provides balanced supporting forces to push the top cover 125 upward.

In some embodiments, the push rods 110 may be mechanically coupled to a driver which automatically controls the push rods 110 to move upward or downward. In some other embodiments, the push rods 110 may be controlled manually by at least one handwheel or other similar drive mechanism.

In some embodiments, after the top cover 125 is pushed off the substrate 100 at a sufficient distance from the substrate 100, the top cover 125 can be held at a fixed height relative to the substrate 100 to allow a space for bonding a semiconductor die onto the substrate 100. In some preferred embodiments, the distance between the top cover 125 and the substrate 100 may be 1 mm. In some other embodiments, the distance may be 0.5 mm to 1.5 mm, or within a range of 0.5 mm to 6 mm, for example.

In some embodiments, the bonding apparatus may further include one or more retainers, which can fix the push rods 110 at the elevated position relative to the substrate 100. Each of the retainers may be a stopper which is operably protruding from the lateral surface of each of the base slots 103. The stopper may be an elongated rod or cuboid block movable in a horizontal direction (i.e., be perpendicular to the moving direction of the respective push rod 110) with respective to the bonding platform. The base portion 101 may also include multiple pairs of grooves. Each pair of the grooves may include two grooves arranged in two opposite positions of the respective base slot 103, and both of the grooves are connected with the base slot 103. Each of the stoppers may be operated to switch between a released position and an extended position. To be more specific, before the push rods 110 are moved upward, the stopper may be in the released position, where it is retracted within a respective groove to allow the push rod 110 to pass through the base slot 103. Once the push rod 110 reaches the elevated position and the top cover 125 is pushed off the substrate 100 at a sufficient height, the stopper may be extended from the groove and enter into the other groove at the opposite position to support the push rod 110 and prevent the push rod 110 from falling down, which may be referred to as the extended position. When it is needed to move the top cover 125 down in a subsequent step, the stopper may be retracted back into the groove in the released position. In addition, one of the grooves in each pair of the grooves may be extended from the lateral surface of the base slot 103 to the lateral surface of the base portion 101 of the bonding platform. As such, at least a portion of the stoppers may be extended out of the bonding platform, which is convenient for users to operably push the stoppers in and out of the groove.

As shown in FIG. 1C, the jig 120 may be vertically moved down onto the top surface of the base portion 101. The downward movement of the jig 120 may be controlled by the rail 130 before, during, or after the step when the top cover 125 is pushed upward off the substrate 100. As such, both of the top surface and the bottom surface of the substrate 100 may be exposed, which may reduce undesired deformation such as expansion or shrinkage of the substrate 100 during a laser compression bonding (LCB) process that may be subsequently conducted.

Next, as shown in FIG. 1D, a semiconductor die 140 with solder bumps 150 formed on its back surface is placed onto the substrate 100. A flux material may also be formed on each of the solder bumps 150. To be more specific, the solder bumps 150 and the flux material are attached onto conductive pads which are formed on the top surface of the substrate 100. It can be appreciated that the conductive pads may be exposed portions of interconnect wires formed within the substrate 100. Electrical connection is desired to be formed between the semiconductor die 140 and the substrate 100 through the solder bumps 150 and the conductive pads which can be later bonded together as described below.

As shown in FIG. 1D, the bonding apparatus also includes a compression head 141 and a laser source 142 above the compression head 141. The semiconductor die 140 is pressed against the substrate 100 by the compression head 141. At the same time, a laser beam is illuminated to the semiconductor die 140 through the compression head 141 by turning on the laser source 142. The laser beam can heat the semiconductor die 140 and solder bumps 150 to facilitate the bonding process. When the laser beam is being illuminated, the compression head 141 is in contact with the semiconductor die 140 and securely holds the semiconductor die 140 by vacuum applied in the compression head 141, for example. The temperature of the solder bumps 150 may increase, and the solder bumps 150 may start to melt, reshape and infiltrate on the conductive pads within the substrate 100, forming respective joints or electrical connection between the semiconductor die 140 and the substrate 100. During the process when the solder bumps 150 are heated and pressed against the substrate 100, the top cover 125 is lifted above the substrate 100, e.g., 0.5 mm˜1.5 mm above the top surface of the substrate 100, or even higher. Since the top cover 125 is not in direct contact with the substrate 100, undesired deformation such as expansion or shrinkage of the substrate 100 may be reduced when the substrate 100 and the solder bumps 150 are being heated, therefore alleviating misalignments between the solder bumps 150 and the conductive pads due to significant deformation of the substrate 100. As such, the joint quality between the semiconductor die 140 and the substrate 100 may be improved by adopting the bonding apparatus to conduct a laser compression bonding process.

After the semiconductor die 140 is bonded with the substrate 100, the laser source 142 may be turned off and the compression head 141 may be removed from the substrate 100. The jig 120 may be vertically moved up by the rail 130 to enable the direct contact between the extended portion of the jig 120 with the bottom surface of the substrate 100, which clamps the substrate 100 again. Next, as shown in FIG. 1E, the push rods 110 may be retracted down through the respective jig holes 122 and the base slots 103 to return to the retracted position, where the push rods 110 are not higher than the jig 120, such that the substrate 100 is supported by the head portion 102 and the top cover 125 is in direct contact with the substrate 100. During the process when the push rods 110 are retracted down, the distance between the top cover 125 and the jig 120 gets smaller, and an attraction force between the magnet 121 and the top cover 125 gets larger. Finally, the top cover 125 is attracted onto the jig 120 by the magnet 121, which covers both of the jig 120 and a periphery of the substrate 100 again with the top cover 125 being in direct contact with the jig 120 and the substrate 100. The push rods 110 may continue to move down through the base slots 103 to bottom parts of the base slot 103.

In some embodiments, a buffer layer may be formed on a bottom surface of the top cover 125. When the top cover 125 is getting closer to the jig 120, the buffer layer may alleviate collision between the top cover 125 and the substrate 100, therefore reducing mechanical damages to the solder bumps 150 at the corner of the semiconductor die 140 and improving the joint reliability.

In some embodiments, for each of the push rods 110, the lateral surface of the push rod 110, i.e., the enlarged head of the push rod 110 may be in direct contact with the lateral surface of the base slot 103. Therefore, when the push rod 110 moves down through the corresponding base slot 103, a retraction speed may be slowed down due to a friction between the lateral surface of the base slot 103 and the push rod 110. In this way, the collision between the top cover 125 and the substrate 100 may be further alleviated since the top cover 125 gets close to the jig 120 more slowly, which also reduces the mechanical damages to the solder bumps 150 at the corner of the semiconductor die 140. It can be appreciated that an additional layer with an exposed rough surface may be attached on the inner walls of the base slot 103. The additional layer may have a serrated surface, for example, to further increase friction between the push rod 110 and the inner walls of the base slot 103.

In some other embodiments, the magnet 121 may also be designed to be less magnetic, for example, with a smaller size, resulting in gentler collision of the top cover 125 to the jig 120. It can also be appreciated that a magnetic shielding layer may be disposed between the top cover 125 and the magnet 121 to reduce the attraction force between the jig 120 and the top cover 125. In some cases, the magnet 121 may be placed at the bottom of the jig 120 to reduce the attraction force.

Next, as shown in FIG. 1F, the bonding platform is moved away from the top cover 125, the substrate 100 and the jig 120, which allows for sufficient room for subsequent processes. Afterwards, a flux cleaning process may be conducted to remove residuals of the flux material to ensure an efficient connection between the semiconductor die 140 and the substrate 100. The flux material may include a water soluble flux material. During the flux cleaning process, de-ionized water may be applied to remove the flux material. The top cover 125 can cover at least a portion of the substrate 100, therefore preventing potential risks of the solder bumps to crack at the corner of the semiconductor die 140 which may be induced by water pressure applied to the semiconductor die 140.

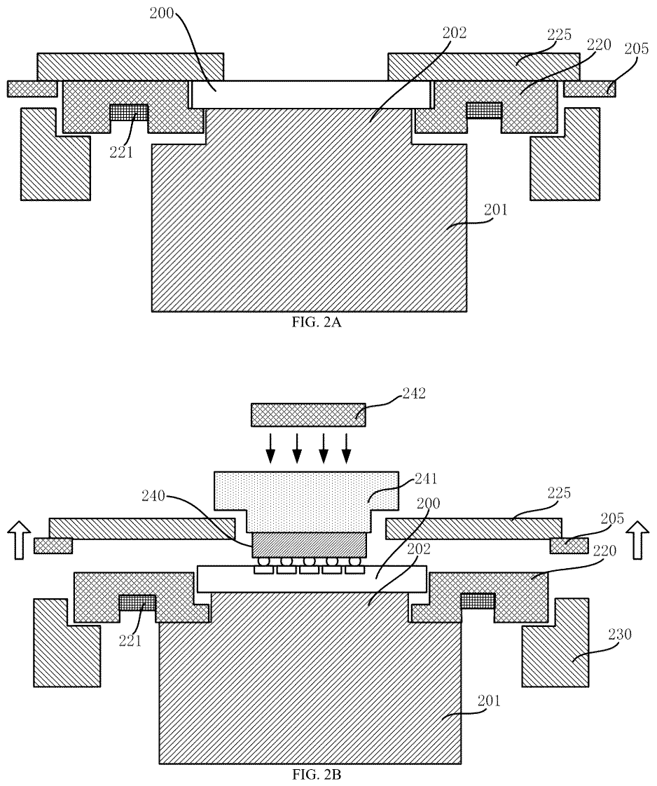

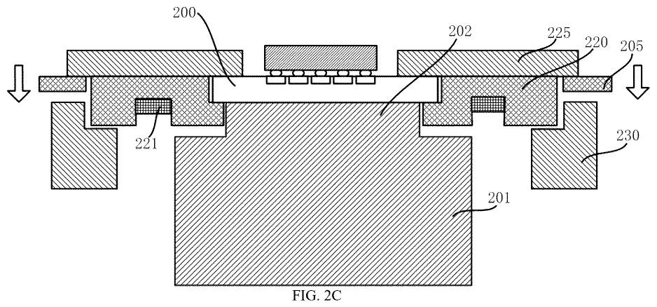

FIGS. 2A to 2C illustrate various steps of a bonding method implemented by a bonding apparatus according to a second embodiment of the present application.

As shown in FIG. 2A, a bonding apparatus is used to bond a semiconductor die onto a substrate. The bonding apparatus includes a bonding platform which further includes a base portion 201 and a head portion 202 extending upward from the base portion 201. A jig 220 is disposed around the head portion 202 of the bonding platform, and has at least one magnet 221 embedded within the jig 220. The substrate 200 may be clamped by the jig 220 at a periphery of the substrate 200. A top cover 225 is attached to the jig 220 and covers a portion of the top surface of the substrate 200 at its periphery. Therefore, the substrate 200 may then be clamped between the top cover 225 and the jig 220. In some embodiments, the bonding platform may be placed below and away from the substrate 200, and therefore the bonding platform may be moved towards the top cover 225 and the jig 220 to load the substrate 200 on the head portion 202 of the bonding platform.

As shown in FIG. 2A, the bonding apparatus further includes clamps 205 vertically movable relative to the bonding platform, where each of the clamps 205 may clamp the top cover 225 at its periphery. In FIG. 2A, the clamps 205 are at the retracted position which allows the top cover 225 to be in direct contact with the jig 220 and the substrate 200.

Next, as shown in FIG. 2B, the clamps 205 may be lifted relative to the bonding platform to an elevated position such that the top cover 225 is pushed upward off the substrate 200 and the jig 220 by the clamps 205. The clamps 205 may be mechanically coupled to a driver which automatically controls the clamps 205 to move upward or downward. In some other embodiments, the clamps 205 may be controlled manually by at least one handwheel or other similar drive mechanism. In some embodiments, the jig 220 may be vertically moved down onto the top surface of the base portion 201. The downward movement of the jig 220 may be controlled by a rail 230 before, during, or after the step when the top cover 225 is lifted off the substrate 200.

Next, a semiconductor die 240 with solder bumps formed on its back surface is placed onto the substrate 200. A flux material may also be formed on each of the solder bumps. The bonding apparatus also includes a compression head 241 and a laser source 242 disposed above the compression head 241. The semiconductor die 240 is pressed against the substrate 200 by the compression head 241. At the same time, a laser beam is illuminated to the semiconductor die 240 through the compression head 241. The laser beam can heat the semiconductor die 240 and solder bumps to facilitate the bonding process, forming electrical connection and joint between the semiconductor die 240 and the substrate 200.

Next, as shown in FIG. 2C, after the semiconductor die 240 is bonded with the substrate 200, the laser source 242 may be turned off and the compression head 241 may be removed from the substrate 200. The jig 220 may be vertically moved up by the rail 230 to be in direct contact with the bottom surface of the substrate 200 to clamp the substrate 200 again. The clamps 205 are then lowered down to a retracted position such that the top cover 225 is in direct contact with the substrate 200 and covers a periphery of the substrate 200, which prevents potential risks of solder bumps to crack at the corner of the semiconductor die 240 which may be induced by water pressure applied to the semiconductor die 240 during a subsequent flux cleaning process.

In some other embodiments, the top cover 225 may be moved upward or downward relative to the bonding platform by other vertically movable actuators such as a movable sucker capable of absorbing the substrate 200.

While the exemplary bonding apparatus and bonding method of the present application is described in conjunction with corresponding figures, it will be understood by those skilled in the art that modifications and adaptations to the bonding apparatus and bonding method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A bonding apparatus, comprising:
a bonding platform configured for operably holding a substrate, wherein the bonding platform comprises:
a base portion;
a head portion extending upward from the base portion and configured for supporting the substrate when the bonding platform is holding the substrate; and
base slots formed in the base portion and around the head portion;
a jig disposed around the head portion of the bonding platform and configured for clamping the substrate, wherein the jig comprises jig holes each extending vertically within the jig and being aligned with one of the base slots;
a top cover operably attached to the jig and configured for covering at least a portion of a top surface of the substrate when the top cover is attached to the jig; and
push rods each being at least partially accommodated within one of the base slots and vertically movable relative to the bonding platform between a retracted position and an elevated position; wherein in the retracted position, the push rods are not higher than the jig such that the substrate is supported by the head portion and the top cover is in direct contact with the substrate; and in the elevated position, the push rods move through the respective jig holes and extend from the jig such that the top cover is pushed upward off the substrate and the jig.

2. The bonding apparatus of claim 1, wherein the jig comprises at least a magnet embedded within the jig and configured for attracting the top cover when the jig and the top cover are moved close to each other.

3. The bonding apparatus of claim 2, wherein the top cover comprises stainless steel.

4. The bonding apparatus of claim 1, wherein the bonding platform has air vents disposed on the head portion and being fluidly coupled to a vacuum source to apply a vacuum pressure to the substrate when the bonding platform is holding the substrate.

5. The bonding apparatus of claim 1, further comprising:
a buffer layer disposed on a bottom surface of the top cover.

6. The bonding apparatus of claim 1, further comprising:
a compression head configured for compressing a semiconductor die against the substrate.

7. The bonding apparatus of claim 6, further comprising:
a laser source configured for illuminating a laser beam to the semiconductor die when it is pressed against the substrate by the compression head.

8. The bonding apparatus of claim 1, further comprising:
a rail being coupled to the jig and configured for moving the jig vertically with respect to the bonding platform.

9. A bonding method, wherein the bonding method is implemented by a bonding apparatus comprising: a compression head, a bonding platform comprising a base portion, a head portion extending upward from the base portion, and base slots formed in the base portion and around the head portion; a jig disposed around the head portion of the bonding platform, wherein the jig comprises jig holes each extending vertically within the jig and being aligned with one of the base slots; a top cover attached to the jig; and push rods each being at least partially accommodated within one of the base slots; and wherein the bonding method comprises:
clamping a substrate between the top cover and the jig to cover at least a portion of a top surface of the substrate by the top cover;
moving the bonding platform towards the top cover and the jig to load the substrate on the head portion of the bonding platform;
moving the push rods through the respective jig holes to an elevated position to push the top cover upward off the jig and the substrate;
placing a semiconductor die onto the substrate and pressing the semiconductor die against the substrate by the compression head to bond the semiconductor die with the substrate via solder bumps; and
retracting the push rods down through the respective jig holes to cover the substrate by the top cover and clamp the substrate between the jig and the top cover.

10. The method of claim 9, wherein the bonding apparatus further comprises a laser source;
and wherein the method further comprises illuminating a laser beam to the semiconductor die via the laser source when pressing the semiconductor die against the substrate by the compression head.

11. The method of claim 9, wherein when pressing the semiconductor die against the substrate by the compression head, the distance between the top cover and the substrate is 0.5 mm˜1.5 mm.

12. The method of claim 9, wherein the jig comprises at least a magnet embedded within the jig and the top cover comprises stainless steel; and wherein when retracting the push rods down through the respective jig holes, the top cover is attracted onto the jig to cover the substrate and the jig.

13. The method of claim 9, wherein
after retracting the push rods down through the respective jig holes to cover the substrate by the top cover, the method further comprises moving the bonding platform away from the top cover and the jig.

14. A bonding apparatus, comprising:
a bonding platform configured for operably holding a substrate, wherein the bonding platform comprises:
a base portion; and
a head portion extending upward from the base portion and configured for supporting the substrate when the bonding platform is holding the substrate;
a jig disposed around the head portion of the bonding platform and configured for clamping the substrate;
a top cover operably attached to the jig and configured for covering at least a portion of a top surface of the substrate when the top cover is attached to the jig; and
actuators each being coupled to the top cover and vertically movable relative to the bonding platform between a retracted position and an elevated position; wherein in the retracted position, the actuators are lowered down such that the substrate is supported by the head portion and the top cover is in direct contact with the substrate; and in the elevated position, the actuators are lifted relative to the bonding platform such that the top cover is pushed upward off the substrate and the jig.

15. The bonding apparatus of claim 14, wherein the actuators comprise clamps each clamping the top cover to vertically elevate or retract the top cover relative to the bonding platform.
